(19) United States
(12) Patent Application Publication
(10) Pub. No.: US 2024/0389308 A1
(43) Pub. Date: Nov. 21, 2024

(54) SEMICONDUCTOR DEVICE

(71) Applicant: Samsung Electronics Co., Ltd., Suwon-si (KR)

(72) Inventors: Dongjun Lee, Suwon-si (KR); Seokhan Park, Suwon-si (KR); Iljae Shin, Suwon-si (KR); Kiseok Lee, Suwon-si (KR); Sanghyun Lee, Suwon-si (KR)

(21) Appl. No.: 18/589,891

(22) Filed: Feb. 28, 2024

(30) Foreign Application Priority Data
May 18, 2023 (KR) 10-2023-0064541

(51) Int. Cl. H10B 12/00; H01L 23/528; H01L 29/08; H01L 29/417

(52) U.S. Cl. CPC H10B 12/485; H01L 23/5283; H01L 29/0847; H01L 29/41725; H10B 12/315; H10B 12/482; H10B 12/488

(57) ABSTRACT

A semiconductor device includes a substrate including a memory cell array region, a contact region, and a connection region, gate electrodes on the memory cell array region and the connection region, and stacked in a vertical direction, active layers on the memory cell array region and stacked in the vertical direction, and conductive connection patterns on the connection region and the contact region, and stacked in the vertical direction, wherein each of the active layers includes a channel region vertically overlapping the gate electrodes, the gate electrodes are electrically connected to the conductive connection patterns, the conductive connection patterns have a step structure including step regions spaced apart from each other, and the step structure has a first step portion stepping down along a first direction and a second step portion facing the first step portion and stepping up along the first direction.

### CROSS-REFERENCE TO RELATED APPLICATION

This application claims benefit of priority to Korean Patent Application No. 10-2023-0064541 filed on May 18, 2023 in the Korean Intellectual Property Office, the disclosure of which is incorporated herein by reference in its entirety.

### BACKGROUND

Example embodiments relate to a semiconductor device and a method of manufacturing the semiconductor device.

To increase the degree of integration of semiconductor devices, research has been conducted to reduce the size of elements constituting semiconductor devices and to improve performance. For example, in a DRAM, research has been conducted to reliably and stably form elements having a reduced size.

### SUMMARY

Example embodiments provide a semiconductor device capable of increasing a degree of integration.

According to example embodiments, a semiconductor device includes a substrate including a memory cell array region, a contact region, and a connection region between the memory cell array region and the contact region; gate electrodes on the memory cell array region and the connection region, the gate electrodes being stacked and spaced apart from each other in a vertical direction on the memory cell array region; active layers on the memory cell array region, the active layers being stacked and spaced apart from each other in the vertical direction on the memory cell array region; and conductive connection patterns on the connection region and the contact region, the conductive connection patterns being stacked and spaced apart from each other in the vertical direction on the connection region, wherein each of the active layers includes a channel region vertically overlapping the gate electrodes, wherein the gate electrodes are electrically connected to the conductive connection patterns on the connection region, wherein the conductive connection patterns have a step structure including a plurality of step regions spaced apart from each other on the contact region, and wherein the step structure has a first step portion stepping down along a first direction and a second step portion facing the first step portion and stepping up along the first direction.

According to example embodiments, a semiconductor device includes a substrate including a memory cell array region, a contact region, and a connection region between the memory cell array region and the contact region; a word line on the memory cell array region and the connection region of the substrate and extending in a first direction, parallel to an upper surface of the substrate; a first conductive pattern on the contact region and the connection region of the substrate and electrically connected to the word line; a second conductive pattern at a vertical level the same as a vertical level of the first conductive pattern, spaced apart from the first conductive pattern in the first direction, and electrically isolated; and an active layer extending in a second direction, parallel to the upper surface of the substrate and perpendicular to the first direction, the active layer including a channel region vertically overlapping the word line . . .

According to example embodiments, a semiconductor device includes a substrate including a memory cell array region, a connection region, and a contact region sequentially arranged in a first direction; gate electrodes on the memory cell array region and the connection region, and the gate electrodes being stacked and spaced apart from each other in a vertical direction; and conductive connection patterns on the contact region and the connection region, and the conductive connection patterns being stacked and spaced apart from each other in the vertical direction, wherein the gate electrodes are electrically connected to the conductive connection patterns on the connection region, wherein the conductive connection patterns have a step structure including a plurality of step regions spaced apart from each other in the first direction on the contact region, and wherein the step structure has a first step portion stepping down along the first direction and a second step portion facing the first step portion and stepping up along the first direction . . .

### BRIEF DESCRIPTION OF DRAWINGS

The above and other aspects, features, and advantages of the present inventive concept will be more clearly understood from the following detailed description, taken in conjunction with the accompanying drawings, in which:

FIGS. 1A, 1B, 2A, 2B, 3A, 3B, 4A, 4B, 5A, 5B, and 6 are diagrams schematically illustrating an example of a semiconductor device according to an example embodiment;

FIGS. 7A and 7B are diagrams schematically illustrating a modified example of a semiconductor device according to an example embodiment;

FIG. 8 is a flowchart schematically illustrating an example of a method of forming a semiconductor device according to an example embodiment; and

FIGS. 9A, 9B, 10-12, 13A, 13B, 14A 14B, 15A, 15B, 16A, 16B, 17A, 17B, 17C, 17D, 18A, 18B, 19, 20A, and 20B show an example of a method of forming a semiconductor device according to an example embodiment.

### DETAILED DESCRIPTION

Hereinafter, terms, such as “upper”, “middle” and “lower” may be replaced with other terms, such as “first”, “second” and “third” and used to describe the elements of the specification. Terms such as “first”, “second”, and “third” may be used to describe various elements, the elements are not limited by the above terms, and a “first element” may be referred to as a “second element”.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

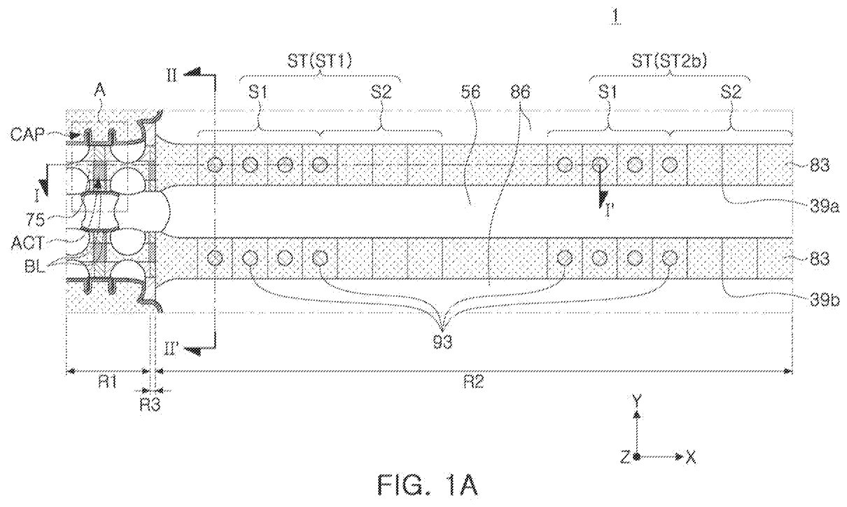

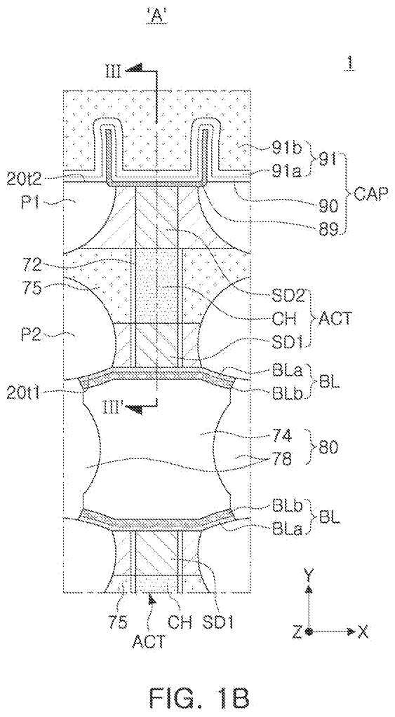

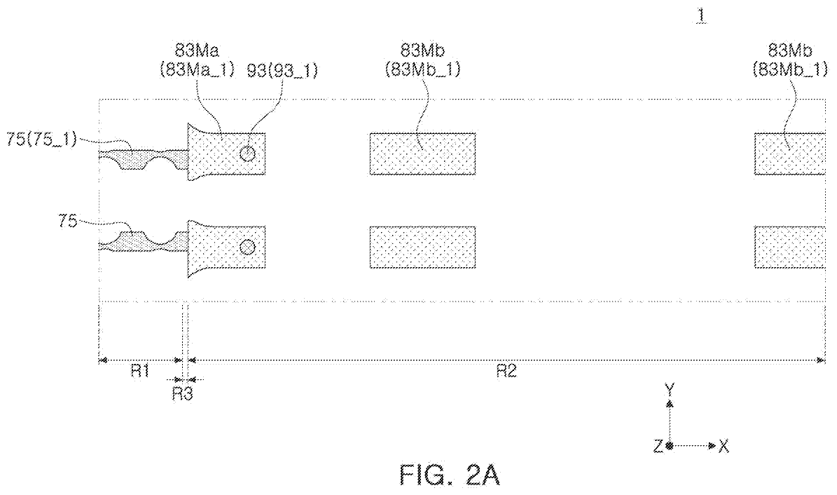

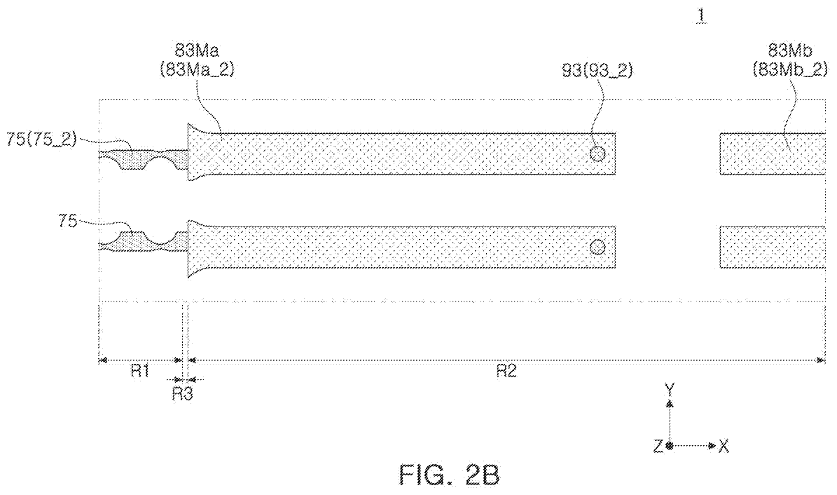

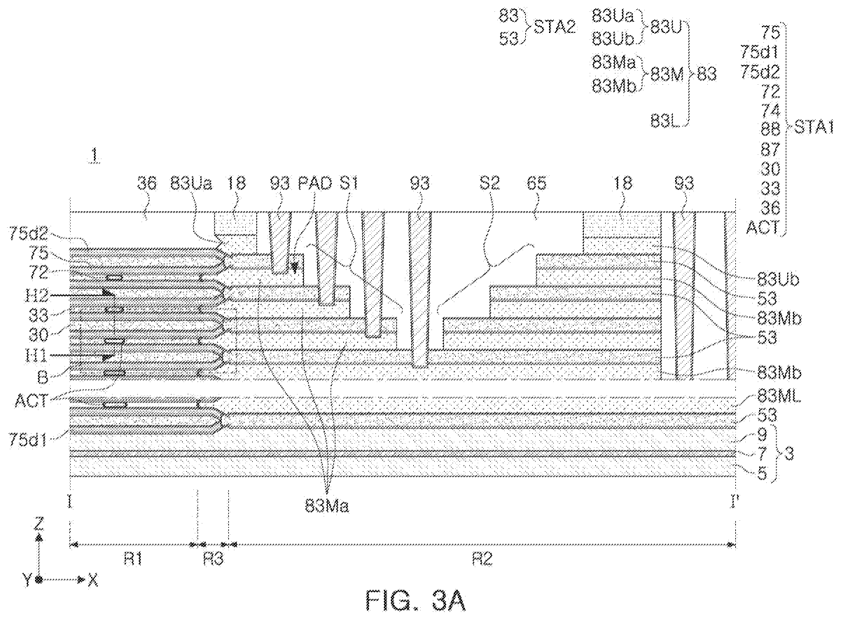

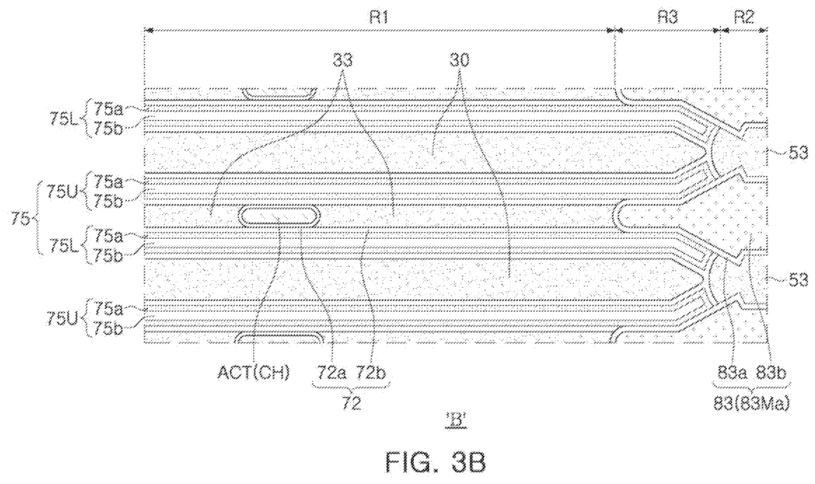

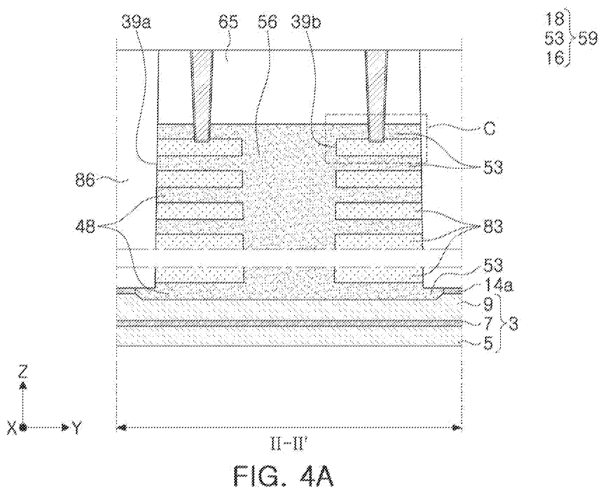

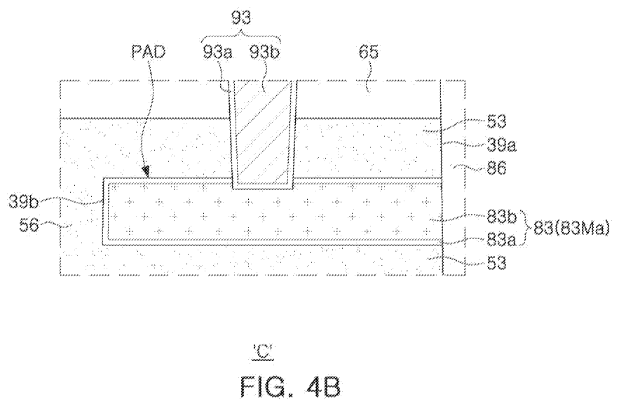

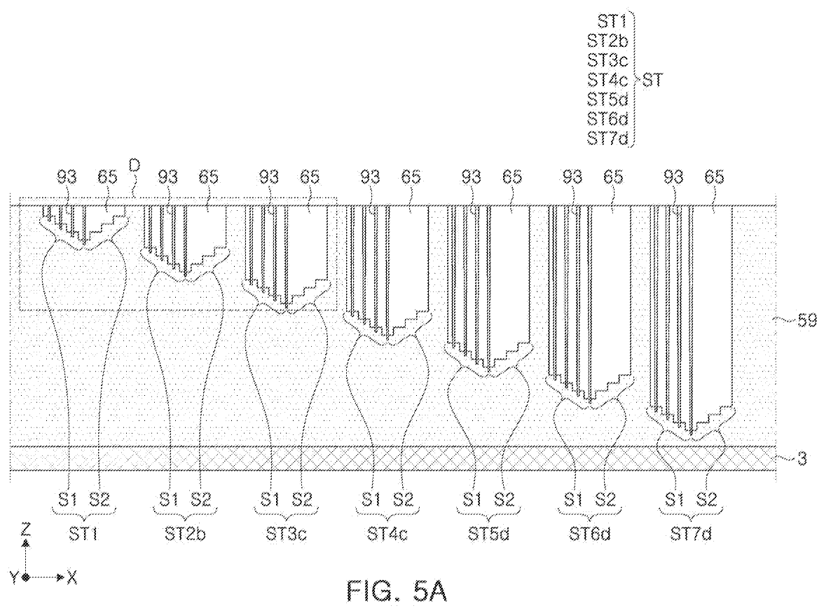

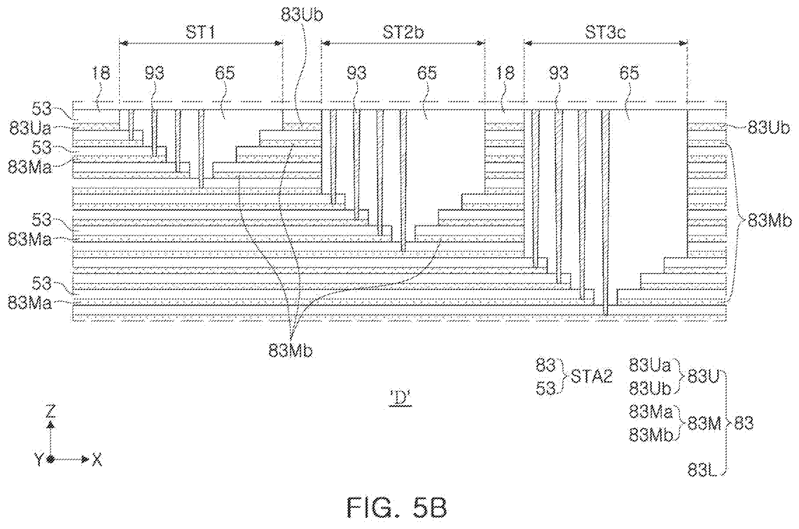

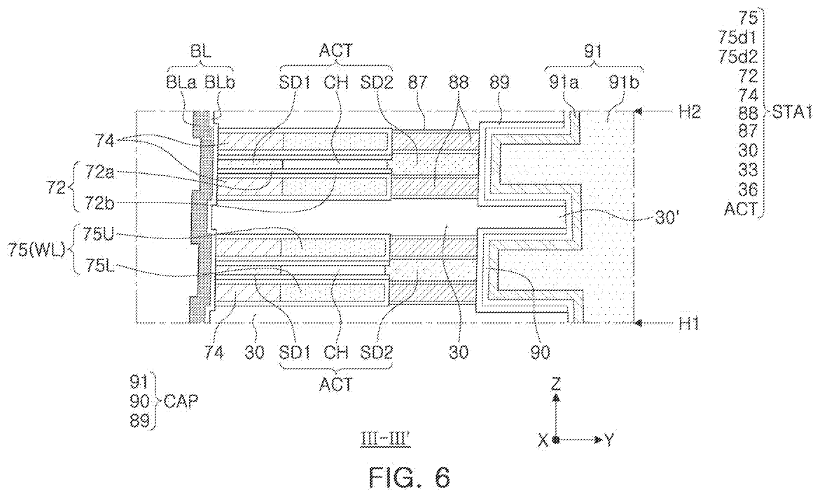

First, an example of a semiconductor device according to an example embodiment will be described with reference to FIGS. 1A to 6. In FIGS. 1A to 4B, FIG. 1A is a top view conceptually illustrating an example of a semiconductor device according to an example embodiment, and FIG. 1B is a partially enlarged view illustrating region ‘A’ in FIG. 1A., FIG. 2A is a top view illustrating some elements of FIG. 1A, FIG. 2B is a top view illustrating some elements of FIG. 1A, FIG. 3A is a cross-sectional view conceptually illustrating a region taken along line I-I′ of FIG. 1A, FIG. 3B is a partially enlarged view illustrating region ‘B’ in FIG. 3A, FIG. 4A is a cross-sectional view conceptually illustrating a region taken along line II-II of FIG. 1A, FIG. 4B is a partially enlarged view illustrating region C′ of FIG. 4A, FIG. 5A is a cross-sectional view conceptually illustrating a portion of a semiconductor device according to an example embodiment, and FIG. 5B is a partially enlarged view illustrating region ‘D’ in FIG. 5A, and FIG. 6 is a cross-sectional view of region H1-H2 of FIG. 3A taken in a second direction Y as well as a cross-sectional view taken along line III-III′ of FIG. 1B taken in the second direction Y.

Referring to FIGS. 1A to 6, a semiconductor device 1 according to an embodiment may include a substrate 3 including a memory cell array region R1, a connection region R3, and a contact region R2 sequentially arranged in a first direction X (see, e.g., FIG. 3A). The memory cell array region R1 may be referred to as a first region, the connection region R3 may be referred to as a second region, and the contact region R2 may be referred to as a third region. The substrate 3 may include at least one semiconductor material layer. For example, the substrate 3 may include a first layer 5, a second layer 7, and a third layer 9 being sequentially stacked. The first and third layers 5 and 9 may be first semiconductor layers, and the second layer 7 may be a second semiconductor layer, different from the first semiconductor layer. For example, a semiconductor material of the first and third layers 5 and 9 may be silicon (Si), and a semiconductor material of the second layer 7 may be silicon-germanium (SiGe).

The semiconductor device 1 may further include first stack structures STA1 and second stack structures STA2.

The first stack structures STA1 may be disposed on the memory cell array region R1 and the connection region R3 of the substrate 3. The second stack structures ST2 may be disposed on the contact region R2 and the connection region R3 of the substrate 3. The first stack structures ST1 may contact and be connected to the second stack structures ST2 on the connection region R3.

Anitem, layer, or portion of an item or layer described as extending in a particular direction has a length in the particular direction and a width perpendicular to that direction, where the length is greater than the width.

Spatially relative terms, such as “on”, “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The first stack structures STA1 may extend in the first direction X and may be spaced apart from each other in a second direction Y. The second stack structures STA2 may extend in the first direction X and may be spaced apart from each other in the second direction Y.

Each of the first stack structures STA1 may include conductive layers 75d1, 75, and 75d2 stacked in the vertical direction Z on the memory cell array region R1 and the connection region R3.

The conductive layers 75d1, 75, and 75d2 may include at least one lower conductive layer 75dl, gate electrodes 75 disposed on the at least one lower conductive layer 75dl, and at least one upper conductive layer 75d2 disposed on the gate electrodes 75.

The at least one lower conductive layer 75dl may be a dummy conductive layer. The at least one upper conductive layer 75d2 may be a dummy conductive layer.

In embodiments, an element including the term “dummy” may be an electrically isolated element. For example, a dummy conductive layer may be an electrically isolated conductive layer.

At least some of the gate electrodes 75 may be word lines WL. Each of the gate electrodes 75 may include a lower electrode layer 75L and an upper electrode layer 75U on the lower electrode layer 75L (see, e.g., FIG. 3B). For example, the lower electrode layer 75L and the upper electrode layer 75U that are adjacent to each other and spaced apart from each other in the vertical direction Z may constitute one gate electrode 75.

Each of the lower and upper electrode layers 75L and 75U may be formed of doped polysilicon, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrOx, RuOx, graphene, carbon nanotube, or combinations thereof, but is not limited thereto. For example, each of the lower and upper electrode layers 75L and 75U may include a single layer or multiple layers of the aforementioned materials. For example, each of the lower and upper electrode layers 75L and 75U may include a first material layer 75b and a second material layer 75a covering upper, lower, and side surfaces of the first material layer 75b.

Each of the first stack structures STA1 may further include active layers ACT stacked and spaced apart from each other in the vertical direction Z in the memory cell array region R1 of the substrate 3.

Each of the active layers ACT may include a first source/drain region SD1, a second source/drain region SD2, and a channel region CH between the first and second source/drain regions SD1 and SD2 (see, e.g., FIG. 1B). Each of the active layers ACT may have a bar shape extending in the second direction Y. The first source/drain region SD1, the channel region CH, and the second source/drain region SD2 may be sequentially arranged in the second direction Y. The active layers ACT may be formed of a semiconductor material.

The first direction X and the second direction Y may be parallel to the upper surface of the substrate 3 and may be perpendicular to each other.

The gate electrodes 75 may vertically overlap the channel regions CH of the active layers ACT. Among the gate electrodes 75 and the active layers ACT, the gate electrode 75 may cover at least two surfaces of the channel region CH of the active layer ACT. As shown in FIG. 3B, for example, the gate electrode 75 may cover lower and upper surfaces of the channel region CH. For example, the lower electrode layer 75L of the gate electrode 75 may cover the lower surface of the channel region CH, and the upper electrode layer 75U of the gate electrode 75 may cover the upper surface of the channel region CH. The channel region CH of the active layer ACT may be disposed between the lower electrode layer 75L of the gate electrode 75 and the upper electrode layer 75U of the gate electrode 75.

Each of the first stack structures STA1 may further include a gate dielectric structure 72 between the gate electrodes 75 and the active layers ACT.

The gate dielectric structure 72 may include at least one layer. The gate dielectric structure 72 may be formed of or include at least one of silicon oxide and a high-k dielectric. The high-k dielectric may be a dielectric having a dielectric constant higher than that of silicon oxide. The high-k dielectric may include at least one of a metal oxide or a metal oxynitride. For example, the high-k dielectric may be formed of HfO₂, HfSiO, HfSiON, HfTaO, HfTiO, HfZrO, ZrO₂, Al₂O₃, or combinations thereof, but is not limited thereto. For example, the gate dielectric structure 72 may include a first gate dielectric layer 72a directly contacting the active layers ACT and a second gate dielectric layer 72b directly contacting the gate electrodes 75. The first gate dielectric layer 72a may have a shape surrounding each of the active layers ACT. The second gate dielectric layer 72b may cover upper and lower surfaces and at least one side surface of each of the lower and upper electrode layers 75L and 75U.

Each of the first stack structures STA1 may further include first interlayer insulating layers 30 and second interlayer insulating layers 33. The first interlayer insulating layers 30 may be disposed between adjacent ones of the conductive layers 75d1, 75, and 75d2. The second interlayer insulating layers 33 may be disposed on side surfaces of the active layers ACT and may be disposed between the lower electrode layer 75L and the upper electrode layer 75U of each of the gate electrodes 75.

Each of the first stack structures STA1 may further include an upper capping insulating layer 36 disposed on the uppermost upper conductive layer 75d2. The upper capping insulating layer 36 may be formed of or include silicon oxide.

In the cross-sectional structure in the second direction Y as shown in FIG. 6, the first stack structure STA1 may further include insulating layers 74 disposed on a first side of the conductive layers 75d1, 75, and 75d2, insulating layers 88 disposed on a second side of the conductive layers 75d1, 75, and 75d2, and insulating layers 87 covering upper and lower surfaces of each of the insulating layers 88. Here, the conductive layers 75d1, 75, and 75d2 may be disposed between the insulating layers 74 and the insulating layers 88.

Each of the second stack structures ST2 may include interlayer insulating layers 53 and conductive connection patterns 83 alternately and repeatedly stacked in the vertical direction Z on the connection region R3 and the contact region R2 and having a step shape on the contact region R2. The vertical direction Z may be perpendicular to the upper surface of the substrate 3.

The conductive connection patterns 83 may be spaced apart from each other in the vertical direction Z on the connection region R3 and the contact region R2 of the substrate 3. Each of the conductive connection patterns 83 may be formed of doped polysilicon, Ti, Ta, Ru, W, Mo, Pt, Ni, Co, TiN, TaN, WN, NON, TiAl, TiAIN, TiSi, TiSiN, TaSi, TaSiN, RuTiN, NiSi, CoSi, IrOx, RuOx, graphene, carbon nanotube, or combinations thereof, but is not limited thereto. For example, each of the conductive connection patterns 83 may include a single layer or multiple layers of the aforementioned materials. For example, each of the conductive connection patterns 83 may include a first material layer 83b and a second material layer 83a covering upper and lower surfaces and at least one side surface of the first material layer 83b (see, e.g., FIG. 4B).

The conductive connection patterns 83 may include a lower conductive connection pattern 83L, intermediate conductive connection patterns 83M disposed on the lower conductive connection pattern 83L, and an upper conductive connection pattern 83U disposed on the intermediate conductive connection patterns 83M.

The intermediate conductive connection patterns 83M include first conductive patterns 85Ma electrically connected to the gate electrodes 75 and second conductive patterns 85Mb facing the first conductive patterns 85Ma and electrically isolated (see, e.g., FIGS. 2A, 2B, and 3A).

When an element is referred to as being “directly connected” or “directly coupled” to another element, or as “contacting” or “in contact with” another element (or using any form of the word “contact”), there are no intervening elements present at the point of contact.

The first conductive patterns 85Ma may be electrically connected to the gate electrodes 75 and the second conductive patterns 85Mb may be electrically insulated from the gate electrodes 75. In the connection region R3, the first conductive patterns 85Ma may contact the gate electrodes 75. For example, when viewed from the second direction Y (e.g., when viewing a cross-section in the X-Z plane), the lower electrode layer 75L may be bent while contacting the lower surface of the first conductive pattern 83Ma and the upper electrode layer 75U may be bent while contacting the upper surface of the first conductive pattern 83Ma on the connection region R3.

The upper conductive connection pattern 83U may include a first upper conductive pattern 83Ua contacting the upper conductive pattern 75d2 and a second upper conductive pattern 83Ub spaced apart from the first upper conductive pattern 83Ua in the first direction X and electrically isolated.

On the contact region R2 of the substrate 3, the conductive connection patterns 83 may have a step structure ST. FIG. 5A is a conceptual cross-sectional view illustrating a step shape of the step structure ST of the conductive connection patterns 83, and FIG. 5B is a partially enlarged view of region ‘D’ in FIG. 5A.

The step structure ST of the conductive connection patterns 83 may include a plurality of step regions ST1, ST2b, ST3c, ST4c, ST5d, ST6d, and ST7d in FIG. 5A spaced apart from each other. Each of the plurality of step regions ST1, ST2b, ST3c, ST4c, ST5d, ST6d, and ST7d may have a step-shaped first step portion S1 lowered (e.g., stepping down) in the first direction X and a step-shaped second step portion S2 facing the first step portion S1 and raised (e.g., stepping up) in the first direction X. For example, among the intermediate conductive connection patterns 83M, the first conductive patterns 83Ma may have the first step portion S1, and the second conductive patterns 83Mb may have the second step portion S2. The first conductive patterns 83Ma may include gate pad regions PAD arranged in a step shape of the first step portion S1. For example, as shown in FIG. 3A, in the first step portion S1, a conductive connection pattern 83 may protrude farther in a positive first direction X than another conductive connection pattern 83 that is above the conductive connection pattern 83. For example, in the second step portion S2, a conductive connection pattern 83 may protrude farther in a negative first direction X than another conductive connection pattern 83 that is above the conductive connection pattern 83.

In embodiments, the first conductive patterns 83Ma may be referred to as gate connection patterns, and the second conductive patterns 83Mb may be referred to as dummy patterns.

Among the intermediate conductive connection patterns 83M, the first intermediate conductive connection patterns 83Ma_1 and 83Mb_1 located on a first height level may include a first conductive pattern 83Ma_1 contacting the first gate electrode 75_1 among the gate electrodes 75 and a plurality of second conductive patterns 83Mb_1 spaced apart from the first conductive pattern 83Ma_1 in the first direction X.

Among the intermediate conductive connection patterns 83M, the second intermediate conductive connection patterns 83Ma_2 and 83Mb_2 located on a second height level may include a conductive pattern 83Ma_2 contacting the second gate electrode 75_2 among the gate electrodes 75 and a plurality of second conductive patterns 83Mb_2 spaced apart from the first conductive pattern 83Ma_2 in the first direction X.

The plurality of step regions ST1, ST2b, ST3c, ST4c, ST5d, ST6d, and ST7d may be sequentially arranged in the first direction X. For example, the plurality of step regions ST1, ST2b, ST3c, ST4c, ST5d, ST6d, and ST7d may include a first step region ST1, a second step region ST2b, a third step region ST3c, a fourth step region ST4c, a fifth step region ST5d, a sixth step region ST6d, and a seventh step region ST7d sequentially arranged in the first direction X.

The plurality of step regions ST1, ST2b, ST3c, ST4c, ST5d, ST6d, and ST7d may become deeper (e.g., may step down) in the first direction X. For example, as shown in FIGS. 5A and 5B, bottom surfaces of the plurality of step regions ST1, ST2b, ST3c, ST4c, ST5d, ST6d, and ST7d may be disposed on levels lowered (e.g., that are progressively lower) in the first direction X. The first and second step portions S1 and S2 of the second step region ST2b may be disposed on a level lower than that of the first and second step portions S1 and S2 of the first step region ST1. Among the gate pad regions PAD of the conductive connection patterns 83, the gate pad regions disposed in the second step region ST2b may be disposed on a level lower than a level of the gate pad regions disposed in the first step region ST1.

In the second direction Y, each of the gate electrodes 75 may have a first maximum width, and each of the conductive connection patterns 83 may have a second maximum width greater than the first maximum width (see, e.g., FIGS. 2A and 2B).

In the first direction X, side surfaces of the gate electrodes 75 may be mis-aligned with side surfaces of the conductive connection patterns 83. For example, when viewed in plan view, a center line of the gate electrode 75 is not collinear with a center line of the conductive connection pattern 83 (see, e.g., FIGS. 2A and 2B).

The semiconductor device 1 may further include bit lines BL and data storage structures CAP.

Each of the bit lines BL may extend in the vertical direction Z (see, e.g., FIG. 6). Each of the bit lines BL may be electrically connected to the first source/drain regions SD1 of the active regions ACT stacked in the vertical direction Z and spaced apart from each other.

The bit lines BL may be formed of polysilicon, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrOx, RuOx, graphene, carbon nanotubes, or combinations thereof, but is not limited thereto. For example, each of the bit lines BL may include a single layer or multiple layers of the aforementioned materials. For example, each of the bit lines BL may include a first material layer BLb contacting the first source/drain regions SD1 and a second material layer BLa covering the first material layer BLb.

Each of the data storage structures CAP (see, e.g., FIGS. 1A, 1B, and 6) may include first electrodes 89 electrically connected to the second source/drain regions SD2 of the active regions ACT, a second electrode 91 covering the first electrodes 89, and a dielectric layer 90 between the second electrode 91 and the first electrodes 89. The second electrode 91 may include a first material layer 91a contacting the dielectric layer 90 and a second material layer 91b covering the first material layer 91a. The interlayer insulating layers 30 may include extension portions 30′ extending between adjacent ones of the first electrodes 89. For example, as shown in FIG. 6, horizontal portions of a cross-section in the Y-Z plane of each of the first electrodes 89 may extend in the second direction Y toward the second source/drain regions SD2. A vertical portion of the cross-section in the Y-Z plane of each of the first electrodes 89 may extend in the third direction Z between the horizontal portions and may contact a corresponding second source/drain region SD2.

In an example, the data storage structure CAP may be a capacitor for storing data in a memory, such as DRAM. The dielectric layer 90 may include a high-k dielectric, silicon oxide, silicon nitride, silicon oxynitride, or combinations thereof.

In another example, the data storage structure CAP may be a structure for storing data of DRAM and other memories, for example, a capacitor for storing data in a ferroelectric memory (FeRAM). For example, the dielectric layer 90 may include a ferroelectric layer capable of recording data using a polarization state.

The semiconductor device 1 may further include an insulating structure 80 (see, e.g., FIG. 1B) covering the bit lines BL and filling a space between adjacent ones of the first stack structures STA1. The insulating structure 80 may include first insulating patterns 74 and second insulating patterns 78 that are alternately disposed in the first direction X. The first insulating patterns 74 may contact the bit lines BL while covering the bit lines BL.

The first stack structures STA1 may have a mirror symmetrical shape with respect to the insulating structure 80. Accordingly, one first stack structure STA1 may be disposed between one insulating structure 80 and one data storage structure CAP.

Hereinafter, among the first stack structures STA1 and the second stack structures STA2, one first stack structure STA1 and one second stack structure STA2 that contact and are connected to each other is mainly described.

The semiconductor device 1 may further include a first gap-fill insulating pattern 56 and a second gap-fill insulating pattern 86 disposed in the contact region R3 (see, e.g., FIGS. 1, 4A, and 4B).

The second stack structure STA2 may be disposed between the first gap-fill insulating pattern 56 and the second gap-fill insulating pattern 86. The first gap-fill insulating pattern 56 may be adjacent to the insulating structure 80 in the first direction X, and the second gap-fill insulating pattern 86 may be adjacent to the data storage structure CAP in the first direction X.

The interlayer insulating layers 53 may extend from the first gap-fill insulating pattern 56. The interlayer insulating layers 53 and the first gap-fill insulating pattern 56 may be formed of or include the same material as each other, for example, silicon oxide.

The semiconductor device 1 may further include a capping insulating layer 65 and contact plugs 93.

The capping insulating layer 65 may be disposed on the plurality of step regions ST1, ST2b, ST3c, ST4c, ST5d, ST6d, and ST7d of the second stack structure STA2 and the first gap-fill insulating pattern 56. The contact plugs 93 may further include contact plugs 93 electrically connected to the gate pad regions PAD that pass through the capping insulating layer 65 and arranged in a step shape. The contact plugs 93 may contact the gate pad regions PAD. Each of the contact plugs 93 may include a first material layer 93b and a second material layer 93a covering side and bottom surfaces of the first material layer 93b.

The semiconductor device 1 may include first insulating pillars P1 that pass through the first stack structure STA1 and are adjacent to the data storage structure CAP and second insulating pillars P2 that pass through the first stack structure STA1 and are adjacent to the insulating structure 80 (see, e.g., FIG. 1B). The first insulating pillars P1 passing through one of the first stack structures STA1 may be arranged to be spaced apart from each other in the first direction X and the second insulating pillars P2 passing through one of the first stack structures STA1 may be arranged to be spaced apart from each other in the first direction X. The first insulating pillars P1 and the second insulating pillars P2 may be spaced apart from each other in the second direction Y.

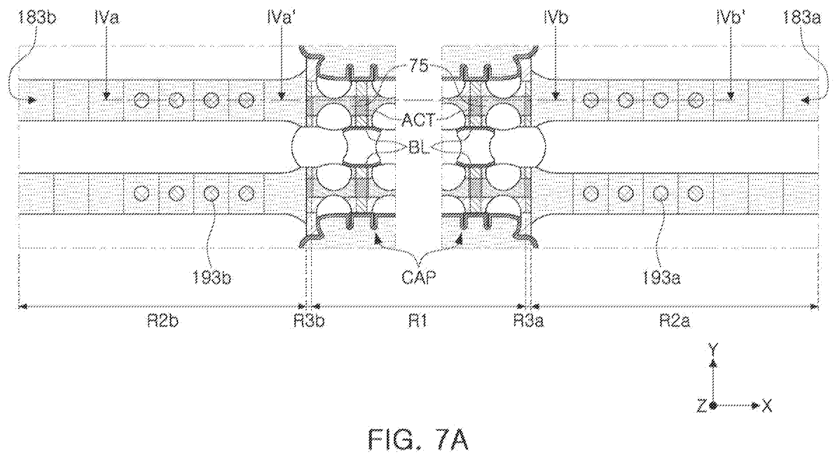

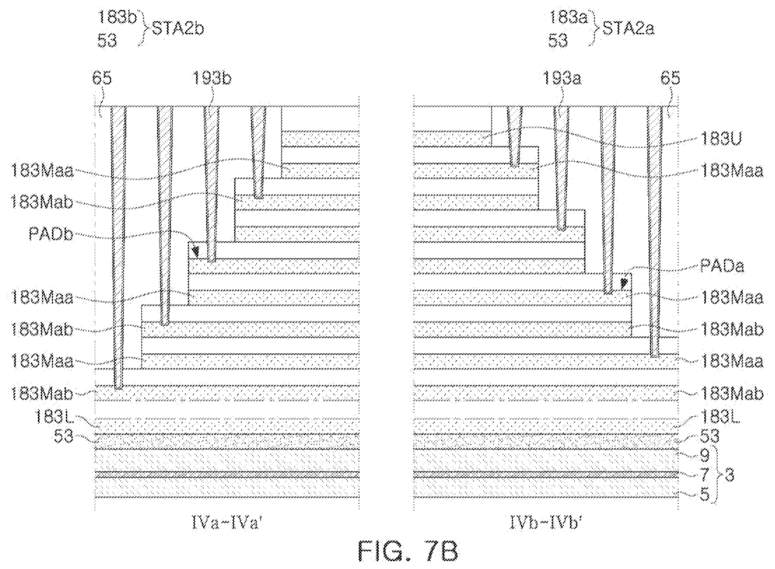

Next, a modified example of a semiconductor device according to an example embodiment will be described with reference to FIGS. 7A and 7B. FIG. 7A is a top view schematically illustrating a modified example of a semiconductor device according to an embodiment, and FIG. 7B is a cross-sectional view schematically illustrating regions taken along lines Iva-Iva and Ivb-Ivb′ of FIG. 7A.

In a modified example, referring to FIGS. 7A and 7B, the substrate 3 described above with reference to FIGS. 1A to 6 may be modified to include a first contact region R2a, a second contact region R2b, a memory cell array region R1 between the first and second contact regions R2a and R2b, a first connection region R3a between the first contact region R2a and the memory cell array region R1, and a second connection region R3b between the second contact region R2b and the memory cell array region R1.

The structure disposed on the memory cell array region R1 of the substrate 3 may be substantially the same as the structures STA1, BL, CAP, and 80 arranged on the memory cell array region R1 of the substrate 3 described above with reference to FIGS. 1A to 6.

The second stack structure STA2 disposed on the connection region R3 and the contact region R2 of the substrate 3 described above with reference to FIGS. 1A to 6 may be modified into a second stack structure STA2a in the first connection region R3a and the first contact region R2a and may be modified into a third stack structure STA2b in the second connection region R3b and the second contact region R2b.

The second stack structure ST2a may include interlayer insulating layers 53 and first side conductive connection patterns 183a alternately and repeatedly stacked in the vertical direction Z in the first connection region R3a and the first contact region R2a and having a step shape on the contact region R2.

The third stack structure ST2b may include interlayer insulating layers 53 and second side conductive connection patterns 183b alternately and repeatedly stacked in the vertical direction Z in the second connection region R3b and the second contact region R2b and having a step shape on the contact region R2.

The first side conductive connection patterns 183a may have a step structure in which the first to seventh step regions (ST1, ST2b, ST3c, ST4c, and ST5d of FIG. 5A) described above with reference to FIG. 5A are sequentially arranged in a direction away from the memory cell array region R1. The second side conductive connection patterns 183b may have a step structure in which the first to seventh step regions (ST1, ST2b, ST3c, ST4c, ST5d, ST6d, and ST7d of FIG. 5A) described above with reference to FIG. 5A are sequentially arranged in a direction away from the memory cell array region R1.

The first side conductive connection patterns 183a and the second side conductive connection patterns 183b may include a lower conductive connection pattern 183L, intermediate conductive connection patterns 183Maa and 183Mab disposed on the lower conductive connection pattern 183L, and an upper conductive connection pattern 183U disposed on the intermediate conductive connection patterns 183Maa and 183Mab. The lower conductive connection pattern 183L may be substantially the same as the lower conductive connection pattern 83L described above, and the upper conductive connection pattern 183U may be substantially the same as the upper conductive connection pattern 83U described above.

The interconnection conductive patterns 183Maa and 183Mab may include first intermediate conductive connection patterns 183Maa and second intermediate conductive connection patterns 183Mab alternately stacked in the vertical direction Z.

The first intermediate conductive connection patterns 183Maa may have first gate pads PADa electrically connected to contact plugs 193a corresponding to the contact plugs 93 described above in the first contact region R2a, and the second intermediate conductive connection patterns 183Mab may have second gate pads PADb electrically connected to the contact plugs 193b corresponding to the contact plugs 93 described above in the second contact region R2b.

At least one second intermediate conductive connection pattern 183Mab may be disposed on a height level between the first gate pads PADa adjacent to each other in the vertical direction Z. At least one first intermediate conductive connection pattern 183Maa may be disposed on a height level between the second gate pads PADb adjacent to each other in the vertical direction Z.

The second intermediate conductive connection pattern 183Mab disposed in the first contact region R2a may be a dummy conductive connection pattern, and the first intermediate conductive connection pattern 183Maa disposed in the second contact region R2b may be a dummy conductive connection pattern.

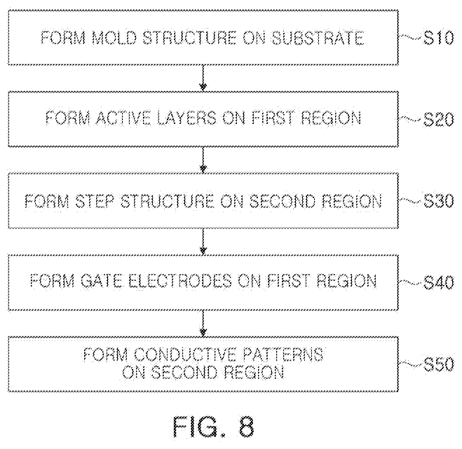

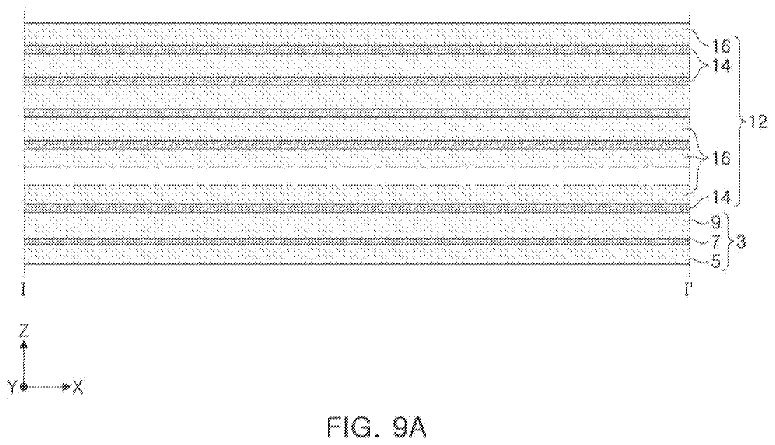

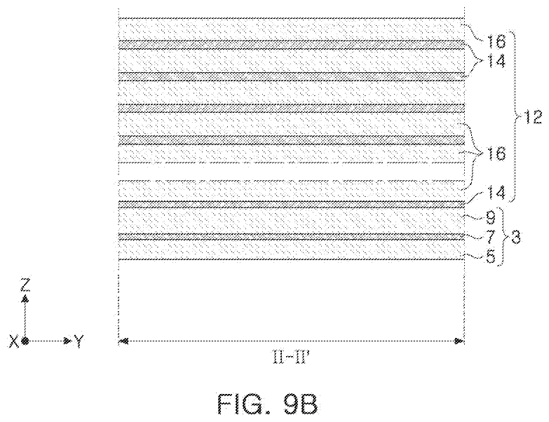

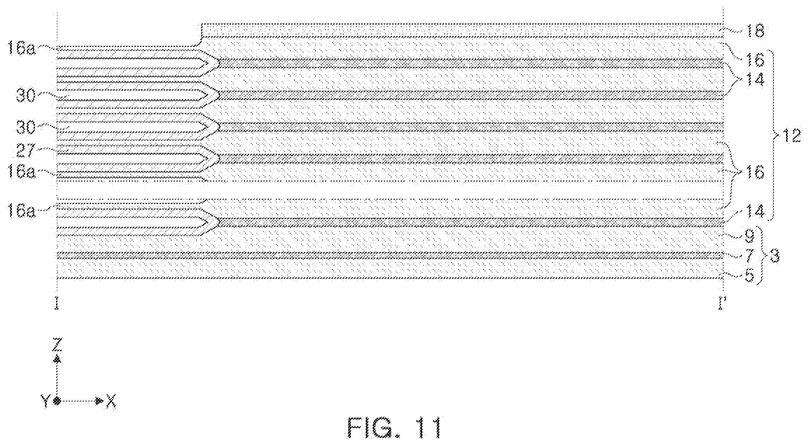

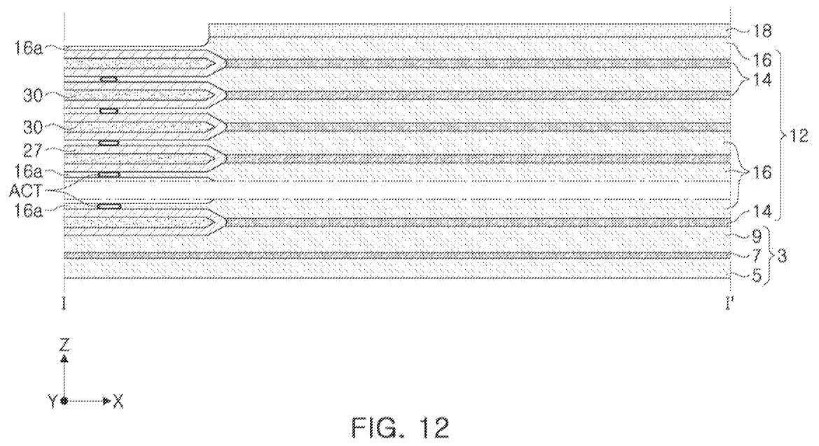

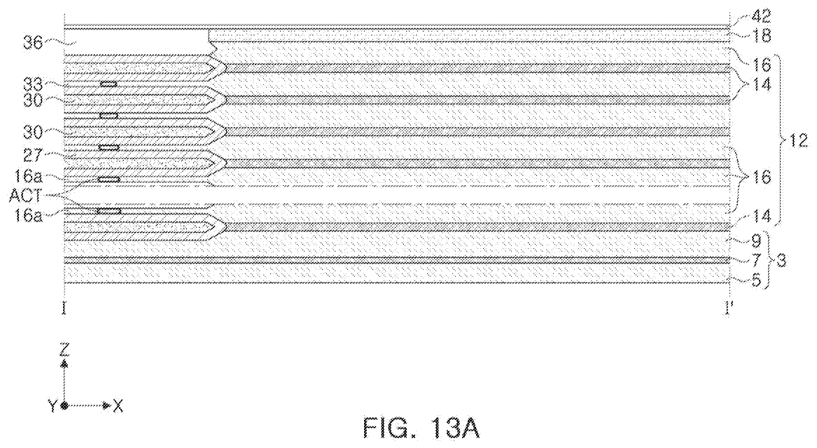

Hereinafter, an example of a method of forming a semiconductor device according to an example embodiment will be described with reference to FIGS. 8 and 20B. In FIGS. 8 to 20B, FIG. 8 is a process flowchart schematically illustrating an example of a method of forming a semiconductor device according to an example embodiment, and FIGS. 9A, 10, 11, 12, 13A, 14A, 15A, 16A, 18A, 19, and 20A are cross-sectional views taken along line I-I′ of FIG. 1A to describe an example of a method of forming a semiconductor device according to an example embodiment, FIGS. 9B, 13B, 14B, 15B, 16B, 18B, and 20B are cross-sectional views taken along line II-II of FIG. 1A to describe an example of a method of forming a semiconductor device according to an example embodiment, and FIGS. 17A, 17B, 17C, and 17D are cross-sectional views illustrating a step structure forming method in a method of forming a semiconductor device according to an example embodiment.

Referring to FIGS. 1A, 1B, 8, 9A, and 9B, a substrate having a first region R1, a second region R2, and a third region R3 between the first region R1 and the second region R2 may be prepared. The substrate 3 may be a semiconductor substrate.

The first region R1 may be a memory cell array region in which memory cells storing data are three-dimensionally arranged, the second region R2 may be a contact region electrically connected to word lines of the memory cell array region, and the third region R3 may be a connection region.

The substrate 3 may be formed of or include at least one semiconductor material layer. For example, the substrate 3 may include a first layer 5, a second layer 7, and a third layer 9 sequentially stacked. The first and third layers 5 and 9 may be first semiconductor layers, and the second layer 7 may be a second semiconductor layer, different from the first semiconductor layer. For example, the semiconductor material of the first and third layers 5 and 9 may be silicon (Si), and the semiconductor material of the second layer 7 may be silicon-germanium (SiGe).

A mold structure 12 may be formed on the substrate 3 (S10). The mold structure 12 may include first mold layers 14 and second mold layers 16 that are alternately and repeatedly stacked. A material of the first mold layers 14 may be different from a material of the second mold layers 16. For example, the material of the first mold layers 14 may be silicon germanium (SiGe), and the material of the second mold layers 16 may be silicon (Si). The uppermost layer of the first and second mold layers 14 and 16 may be the second mold layer 16. The thickness of each of the second mold layers 16 may be greater than the thickness of each of the first mold layers 14.

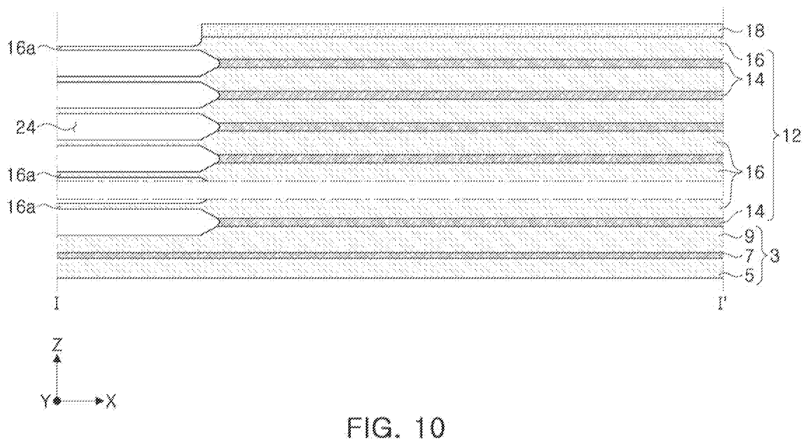

Referring to FIGS. 1A, 1B, and 10, a mask layer 18 may be formed on the mold structure 12. The mask layer 18 may have an opening on the mold structure 12 in the first region R1.

Line-shaped first insulating pillars (a position of 80 in FIG. 1B) and second insulating pillars (a position of CAP in FIG. 1B) filling first and second trenches (20t1 and 20t2 in FIG. 1B) passing through the mold structure 12 in the first region R1 and the third region R3 may be formed, first and second holes (positions of P1 and P2 in FIG. 1B) passing through the mold structure 12 in the first region R1 are formed to expose side surfaces of the first and second mold layers 14 and 16, the first mold layers 14 of the mold structure 12 in the first region R1 may be removed to form openings 24, and the second mold layers 16 of the first mold structure 12 in the first region R1 exposed by the openings 24 may be partially etched to form second mold patterns 16a having a reduced thickness. The second mold patterns 16a in the first region R1 may continuously extend from the second mold layers 16 in the second region R2.

Referring to FIGS. 1A, 1B, and 1I, an insulating liner layer 27 and a first interlayer insulating layer 30 filling the openings (24 in FIG. 10) may be formed. Forming the insulating liner layers 27 and the first interlayer insulating layers 30 may include forming the insulating liner layers 27 conformally covering inner walls of the openings (24 in FIG. 10), forming first interlayer insulating layers 34 filling the remaining portions of the openings (24 in FIG. 10), and etching and removing portions other than the remaining portions in the openings (24 in FIG. 10) of the insulating liner layers 27 and the first interlayer insulating layers 30.

The insulating liner layers 27 may be formed of silicon nitride, and the first interlayer insulating layers 30 may be formed of silicon oxide.

Referring to FIGS. 1A, 1B, 8, and 12, active layers ACT may be formed in the first region R1 of the substrate 3 (S20). Forming the active layers ACT may include partially etching the second mold patterns 16a. The active layers ACT may be spaced apart from each other. Each of the active layers ACT may have a line shape extending in the second direction Y.

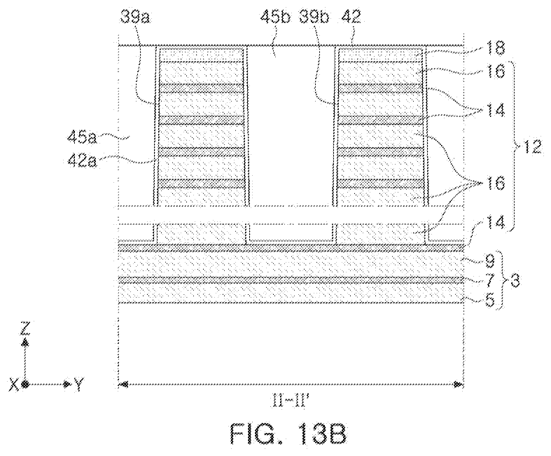

Referring to FIGS. 1A, 1B, 13A, and 13B, second interlayer insulating layers 33 covering side surfaces of the active layers ACT and an upper capping insulating layer 36 covering the uppermost insulating liner layer of the insulating liner layers 27 may be formed.

When the second interlayer insulating layers 33 and the upper capping insulating layer 36, first and second insulating pillars (P1 and P2 in FIG. 1B) filling the first and second holes (positions of P1 and P2 in FIG. 1B) passing through the mold structure 12 in the first region R1 described above with reference to FIG. 10 may be simultaneously formed.

In the second region R2, the mold structure 12 may be patterned to form third and fourth trenches 39a and 39b. Each of the third and fourth trenches 39a and 39b may have a line shape extending in the first direction X. The third and fourth trenches 39a and 39b may be spaced apart from each other in the second direction Y and may be alternately disposed repeatedly. The third and fourth trenches 39a and 39b may pass through the first and second mold layers 14 and 16 located on the lowermost first mold layer 14 among the first and second mold layers 14 and 16 of the mold structure 12 in the second region R2.

A capping liner 42 may be formed on the substrate on which the third and fourth trenches 39a and 39b are formed. A first insulating gap-fill pattern 45a filling the third trench 39a and a second insulating gap-fill pattern 45b filling the fourth trench 39b may be formed on the capping liner 42.

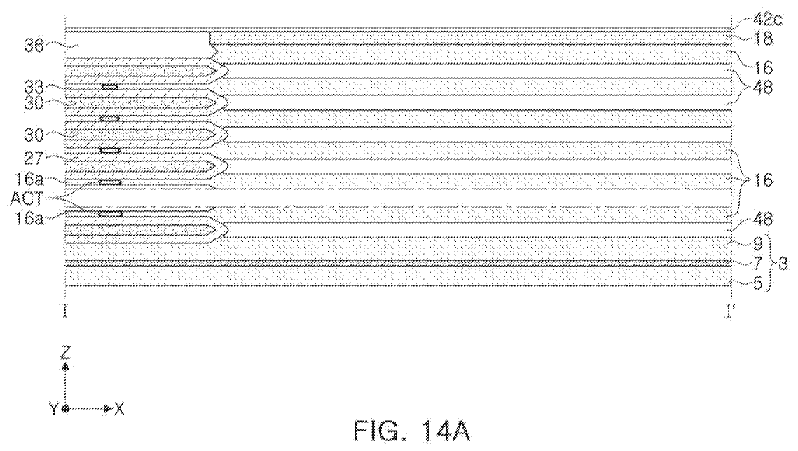

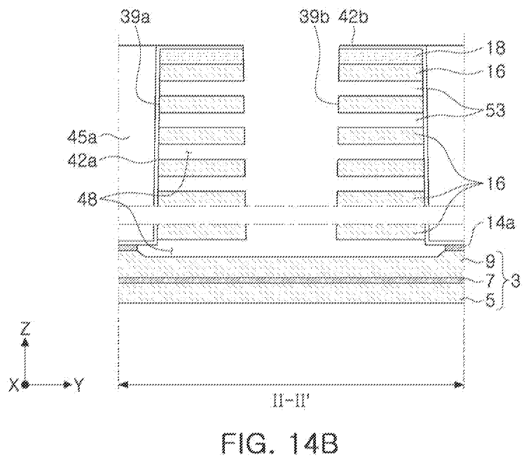

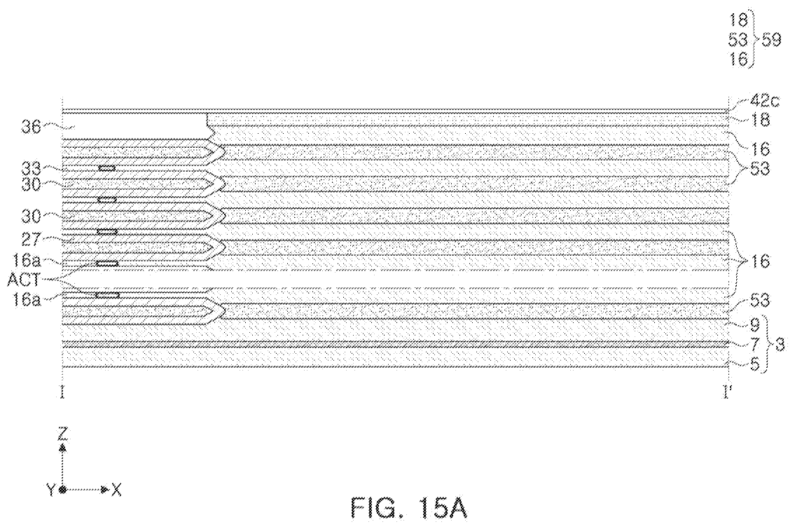

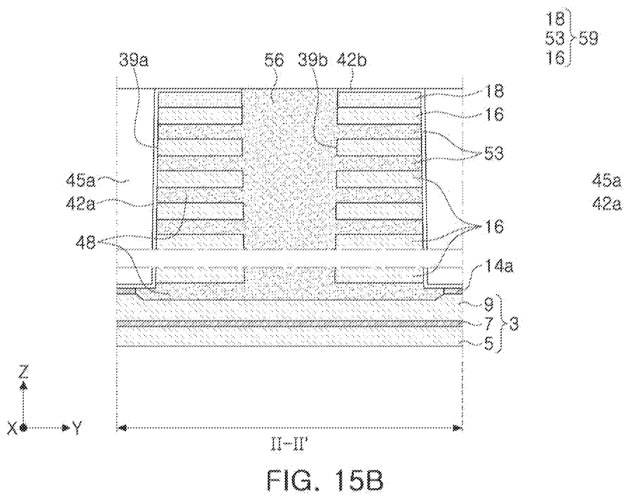

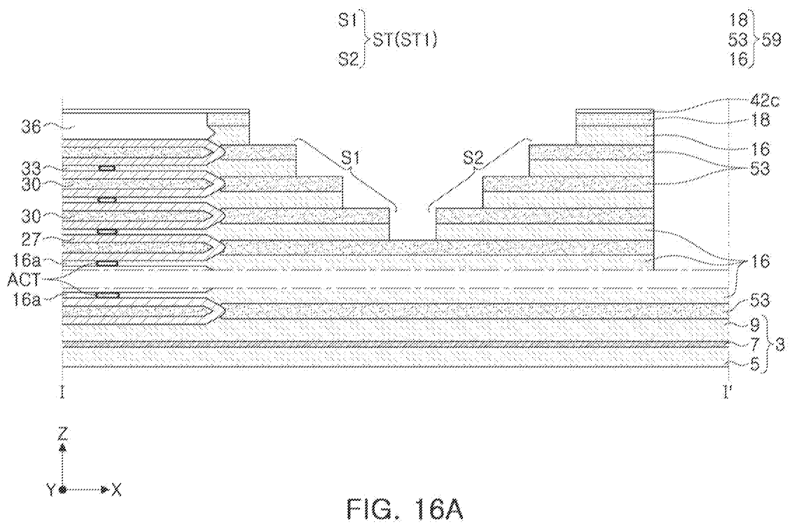

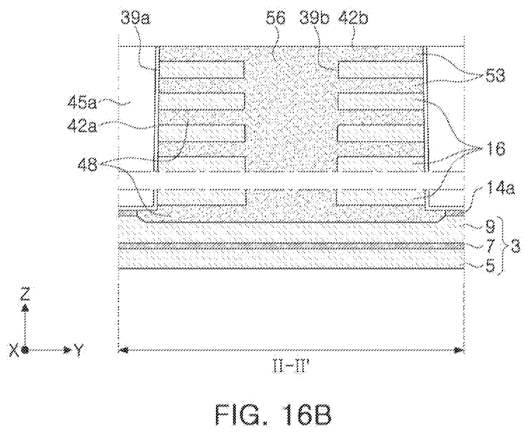

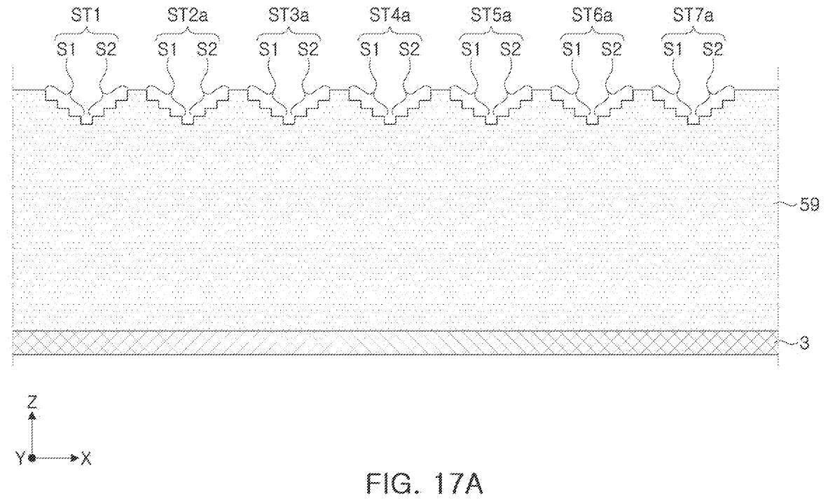

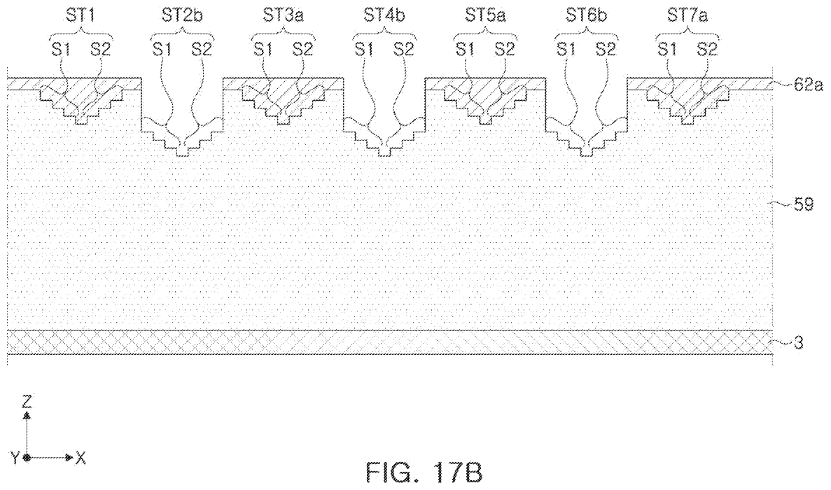

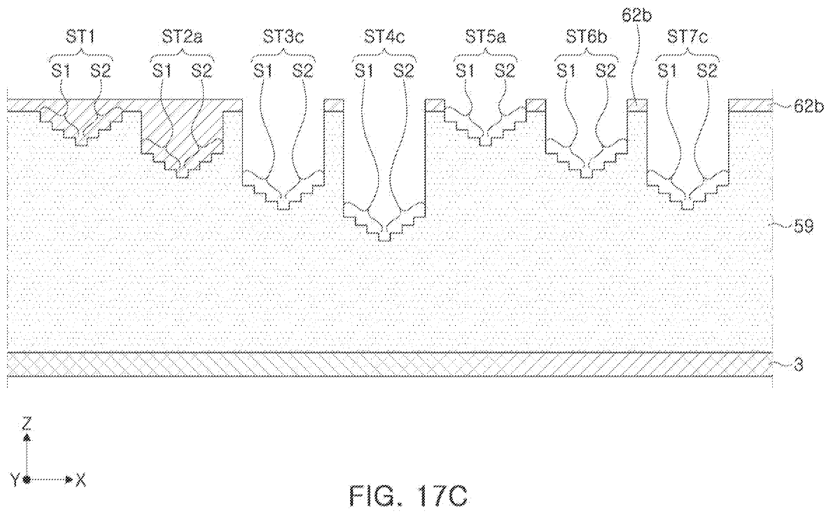

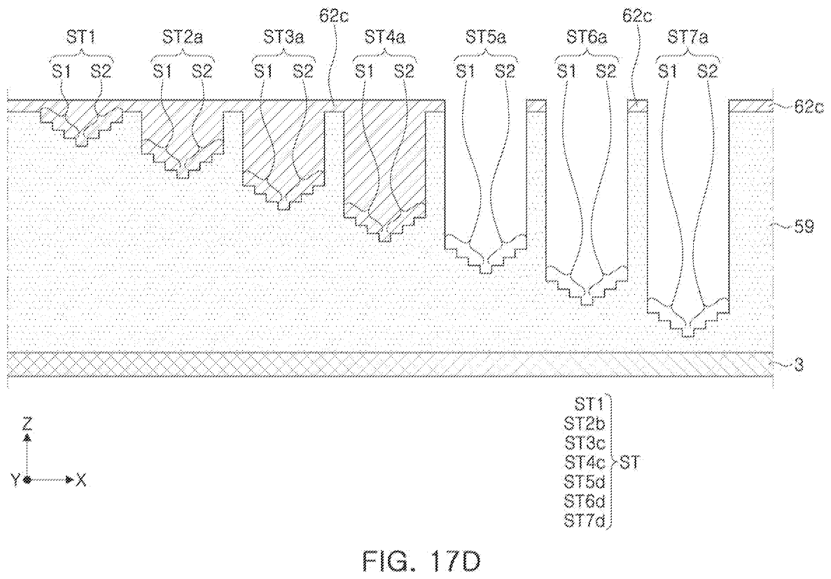

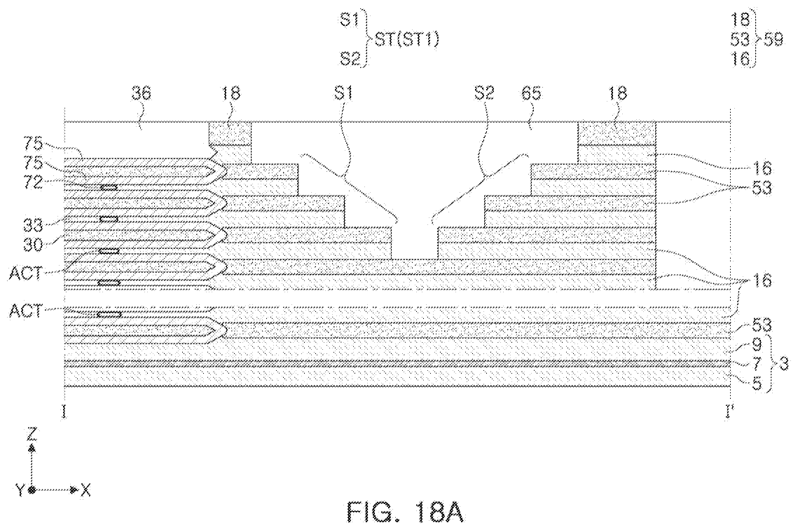

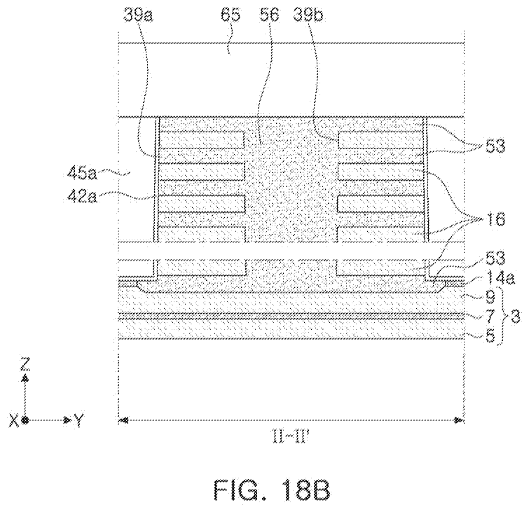

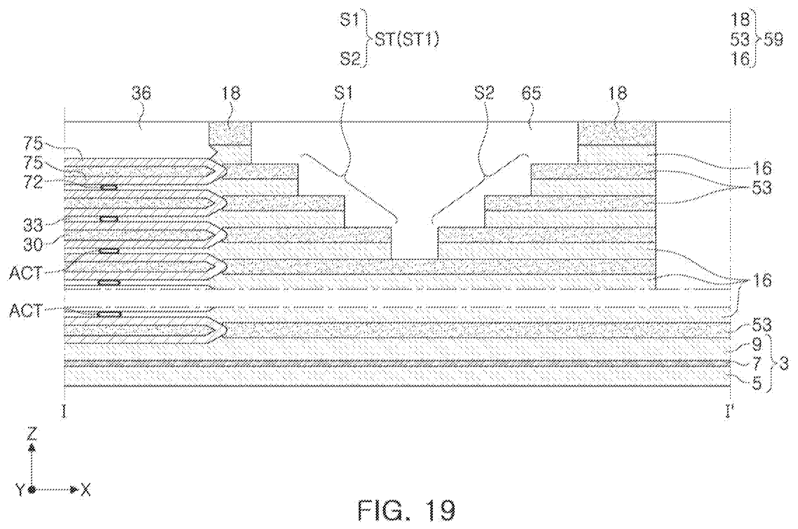

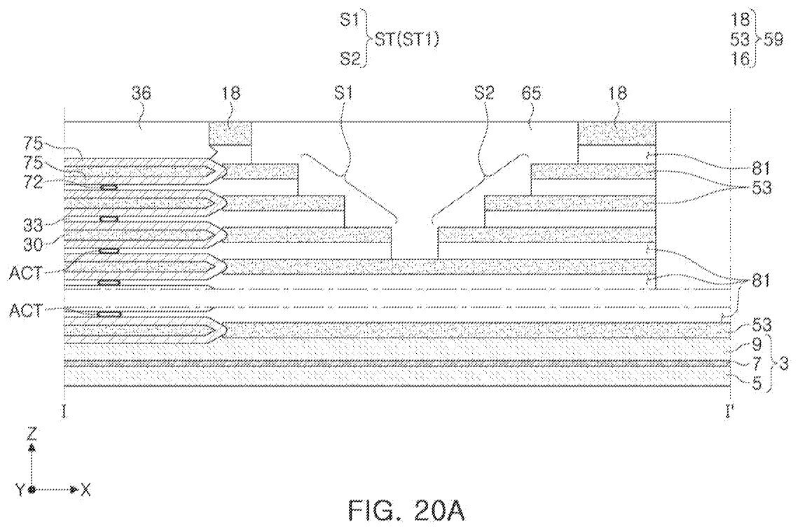

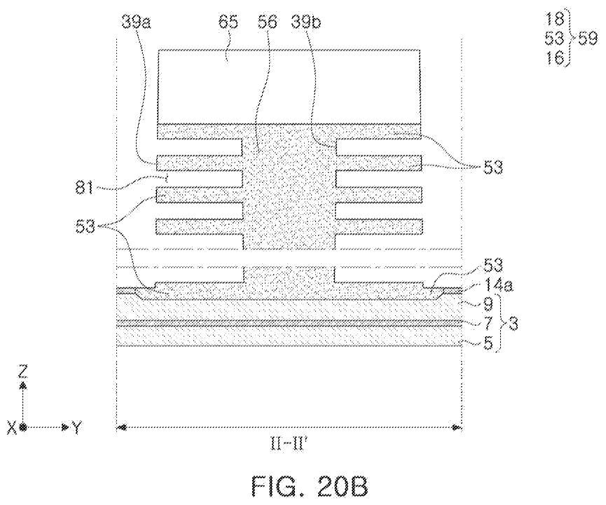

Referring to FIGS. 1A, 1B, 14A, and 14B, the second insulating gap fill pattern (45b in FIG. 13B) and the capping liner (42 in FIG. 13B) in the fourth trench 39b may be removed to expose a side surface and a bottom surface of the second trench 39b. Subsequently, the first mold layers (14 of FIGS. 13A and 13B) exposed by the fourth trench 39b may be etched, and the second mold layers 16 and the third layer 9 exposed by etching and removing the first mold layers (14 in FIGS. 13A and 13B) may be partially etched to form openings 48.

Referring to FIGS. 1A, 1B, 15A, and 15B, an insulating structure filling the openings (48 of FIGS. 14A and 14B) and filling the fourth trench 39b may be formed. The insulating structure may include interlayer insulating layers 53 filling the openings (48 of FIGS. 14A and 14B) and a first gap-fill insulating pattern 56 filling the fourth trench 39b. The interlayer insulating layers 53 and the first gap-fill insulating pattern 56 may be formed of or include the same material, e.g., silicon oxide, formed at the same time.

In the second region R2, the interlayer insulating layers 53, the second mold layers 16, and the mask layer 18 may be referred to as a third mold structure 59.

Referring to FIGS. 1A, 1B, 8, 16A, and 16B, a step structure ST may be formed in the second region R2 (S30).

The step structure ST may be formed by patterning the third mold structure 59 in the second region R2. In order to form the step structure ST, the gap-fill insulating patterns 45a and 56 may be patterned together, while the third mold structure 59 is patterned.

The step structure ST may include a plurality of step regions spaced apart from each other. Each of the plurality of step regions may include a first step shape S1 lowered (e.g., stepping down) in the first direction X and a second step shape S2 raised (e.g., stepping up) in the first direction X. FIG. 16A illustrates a first step region ST1 among the plurality of step regions.

An example of a method of forming the plurality of step regions will be described with reference to FIGS. 17A to 17D. FIGS. 17A to 17D are cross-sectional views conceptually illustrating the substrate 3 and the third mold structure 59 in the second region R2.

Referring to FIG. 17A, a plurality of step regions ST1, ST2a, ST3a, ST5a, ST6a, and ST7a may be formed by performing a first patterning process. Each of the plurality of step regions ST1, ST2a, ST3a, ST5a, ST6a, and ST7a has a first step shape S1 lowering in the first direction X and a second step rising in the first direction X. 2 may include a step shape (S2)

The plurality of step regions ST1, ST2a, ST3a, ST5a, ST6a, and ST7a may include a first step region ST1, a second preliminary step region ST2a, a third preliminary step region ST3a, a fourth preliminary step region ST4a, a fifth preliminary step region ST5a, a sixth preliminary step region ST6a, and a seventh preliminary step region ST7a sequentially arranged in the first direction X.

Referring to FIG. 17B, a second step region ST2b, a fourth preliminary step region ST4b, and a sixth preliminary step region ST6b which are deepened may be formed by performing a second patterning process. Performing of the second patterning process may include exposing the second preliminary step region ST2a, the second preliminary step region ST4a, and the sixth preliminary step region ST6a, forming a first mask 62a, etching the exposed second preliminary step region ST2a, the second preliminary step region ST4a, and the sixth preliminary step region ST6a using the first mask 62a, and removing the first mask 62a.

Referring to FIG. 17C, third step region ST3c, a fourth step region ST4c, and a seventh preliminary step region ST7c which are deepened may be formed by performing a third patterning process. The performing of the third patterning process may include forming a second mask 62b exposing the third preliminary step region ST3a, the fourth preliminary step region ST4b, and the seventh preliminary step region ST7a and covering the remaining region, etching the exposed third preliminary step region ST3a, the fourth preliminary step region ST4b, and the seventh preliminary step region ST7a using the second mask 62b as an etch mask, and removing the second mask 62b.

Referring to FIG. 17D, a fifth step region ST5d, a sixth step region ST6d, and a seventh step region ST7d which are deepened may be formed by performing a fourth patterning process. The performing of the third patterning process may include forming a third mask 62c exposing the fifth preliminary step region ST5a, the sixth preliminary step region ST6b, and the seventh preliminary step region ST7c and covering the remaining region, etching the exposed fifth preliminary step region ST5a, the sixth preliminary step region ST6b, and the seventh preliminary step region ST7c using the third mask 62c as an etch mask, and removing the third mask 62c. Accordingly, a step structure ST having the first to seventh step regions ST1, ST2b, ST3c, ST4c, ST5d, ST6d, and ST7d may be formed.

Referring to FIGS. 1A, 1B, 18A, and 18B, a capping insulating layer 65 covering the step structure ST may be formed. The capping insulating layer 65 may be formed of an insulating material, such as silicon oxide.

Referring to FIGS. 1A, 1B, 8, and 19, a gate replacement process may be performed to replace the insulating liner layers 27 in the first region R1 and the third region R3 with gates 72 and 75. The performing of the gate replacement process may include removing the first insulating pillar (position 80 in FIG. 1B), filling the first and second trenches (20t1 and 20t2 in FIG. 1B) described above with reference to FIG. 10 to expose a side surface and a bottom surface of the first trench (20t1 in FIG. 1B), selectively removing the insulating liner layers 27 exposed by the first trench (20t1 in FIG. 1B) to form openings, and forming gate dielectric layers 72 and conductive layers 75d1, 75, and 75d2 in the openings. The conductive layers 75d1, 75, and 75d2 may include at least one lower conductive layer 75d1, gate electrodes 75 disposed on the at least one lower conductive layer 75d1, and at least one upper conductive layer 75d2 disposed on the gate electrodes 75. Accordingly, the gate electrodes 75 may be formed in the second region R2 (S40).

After the gates 72 and 75 is formed, a conductive layer covering sidewalls of the first trench (20t1 in FIG. 1B) may be formed, an insulating layer filling the first trench (20t1 in FIG. 1B) may be formed, the insulating layer and the conductive layer may be patterned to form the remaining first insulating patterns (74 in FIG. 1B) and the bit lines (72 in FIG. 1B) and simultaneously form openings, and second insulating patterns (78 in FIG. 1B) filling the openings may be formed.

Referring to FIGS. 1A, 1B, 20A, and 20B, side and bottom surfaces of the third trench 39a may be exposed, and the second mold layers 16 exposed by the third trench 39a may be removed to form the openings 81.

Referring back to FIGS. 1A to 6 and 8, conductive connection patterns 83 filling the openings (81 in FIGS. 20A and 20B) may be formed. Accordingly, the conductive connection patterns 83 may be formed in the second region R2 (S50). Subsequently, a second gap-fill insulating pattern 86 may be formed to fill the third trench 39a. Subsequently, among the first insulating pillar (position 80 in FIG. 1B) and second insulating pillar (position of CAP in FIG. 1B) filling the first and second trenches (20t1 and 20t2 in FIG. 1B) described above with reference to FIG. 10, the second insulating pillar (position of CAP in FIG. 1B) may be removed to expose a side surface and a bottom surface of the second trench 20t2.

Side surfaces of the active regions ACT and the first interlayer insulating layers 30 may be exposed by the second trench 20t2. An etching process using the interlayer insulating layers 30 as an etch mask may be performed to partially etch the portions exposed by the second trench 20t2 to form openings, and first electrodes 89 may be formed in the openings. A dielectric layer 90 covering the first electrodes 89 and a second electrode 91 covering the dielectric layer 90 and filling the second trench 20t2 may be formed. The first electrodes 89, the dielectric layer 90, and the second electrode 91 may form a data storage structure CAP. Gate contact plugs 93 electrically connected to the gate pad regions PAD of the conductive connection patterns 83 may be formed.

According to embodiments, the gate electrodes and the active layers stacked in the vertical direction may be provided. The conductive connection patterns electrically connected to the gate electrodes may include the first step portion lowered in the first direction and the second step portion raised in the first direction.

Accordingly, the semiconductor device capable of increasing the degree of integration may be provided. The various beneficial advantages and effects of the present inventive concept are not limited to the above, and will be more easily understood in the process of describing specific embodiments of the present inventive concept.

While example embodiments have been shown and described above, it will be apparent to those skilled in the art that modifications and variations could be made without departing from the scope of the present inventive concept.

What is claimed is:

1. A semiconductor device comprising:
a substrate including a memory cell array region, a contact region, and a connection region between the memory cell array region and the contact region;
gate electrodes on the memory cell array region and the connection region, the gate electrodes being stacked and spaced apart from each other in a vertical direction on the memory cell array region;
active layers on the memory cell array region, the active layers being stacked and spaced apart from each other in the vertical direction on the memory cell array region; and
conductive connection patterns on the connection region and the contact region, the conductive connection patterns being stacked and spaced apart from each other in the vertical direction on the connection region,
wherein each of the active layers includes a channel region vertically overlapping the gate electrodes,
wherein the gate electrodes are electrically connected to the conductive connection patterns on the connection region,
wherein the conductive connection patterns have a step structure including a plurality of step regions spaced apart from each other on the contact region, and
wherein the step structure has a first step portion stepping down along a first direction and a second step portion facing the first step portion and stepping up along the first direction.

2. The semiconductor device of claim 1, wherein each of the active layers has a bar shape extending in a second direction perpendicular to the first direction,
wherein the first direction and the second direction are directions parallel to an upper surface of the substrate,
wherein each of the active layers further includes a first source/drain region and a second source/drain region, and
wherein the channel region is between the first source/drain region and the second source/drain region in each of the active layers.

3. The semiconductor device of claim 2, further comprising:
gate dielectric layers between the channel region of each of the active layers and the gate electrodes;
a bit line electrically connected to the first source/drain region of each of the active layers on the memory cell array region of the substrate; and
a data storage structure electrically connected to the second source/drain region of each of the active layers on the memory cell array region of the substrate.

4. The semiconductor device of claim 3, wherein the data storage structure includes:
first electrodes, each of the first electrodes being electrically connected to the second source/drain region of a corresponding one of the active layers, and the first electrodes being spaced apart from each other in the vertical direction;
a second electrode covering the first electrodes; and
a dielectric layer between the first electrodes and the second electrode.

5. The semiconductor device of claim 1, wherein
the first step portion includes first conductive patterns of the conductive connection patterns, the first conductive patterns being electrically connected to the gate electrodes,
the second step portion includes second conductive patterns of the conductive connection patterns, the second conductive patterns being spaced apart from the first conductive patterns and electrically isolated in the first direction, and
the first conductive patterns include gate pad regions arranged in a step shape in the first step portion.

6. The semiconductor device of claim 5, further comprising contact plugs in contact with the gate pad regions.

7. The semiconductor device of claim 1, wherein in a second direction perpendicular to the first direction, each of the gate electrodes has a first maximum width, and
wherein in the second direction, each of the conductive connection patterns has a second maximum width greater than the first maximum width.

8. The semiconductor device of claim 1, wherein, in the first direction, side surfaces of the gate electrodes are mis-aligned with side surfaces of the conductive connection patterns.

9. The semiconductor device of claim 1,
wherein each of the gate electrodes includes:
a lower electrode layer; and
an upper electrode layer on the lower electrode layer and spaced apart from the lower electrode layer,
wherein the gate electrodes include a first gate electrode,
wherein the conductive connection patterns include a first conductive connection pattern connected to the first gate electrode, and
wherein on the connection region of the substrate, the lower electrode layer and the upper electrode layer are in contact with the first conductive connection pattern.

10. The semiconductor device of claim 9, wherein on the connection region of the substrate, the first conductive connection pattern vertically overlaps the lower electrode layer and the upper electrode layer of the first gate electrode,
wherein the lower electrode layer of the first gate electrode contacts a lower surface of the first conductive connection pattern, and
wherein the upper electrode layer of the first gate electrode contacts an upper surface of the first conductive connection pattern.

11. A semiconductor device comprising:
a substrate including a memory cell array region, a contact region, and a connection region between the memory cell array region and the contact region;
a word line on the memory cell array region and the connection region of the substrate and extending in a first direction, parallel to an upper surface of the substrate;
a first conductive pattern on the contact region and the connection region of the substrate and electrically connected to the word line;
a second conductive pattern at a vertical level the same as a vertical level of the first conductive pattern, spaced apart from the first conductive pattern in the first direction, and electrically isolated; and
an active layer extending in a second direction, parallel to the upper surface of the substrate and perpendicular to the first direction, the active layer including a channel region vertically overlapping the word line.

12. The semiconductor device of claim 11, wherein the word line includes a lower electrode layer and an upper electrode layer spaced apart from each other in a vertical direction, perpendicular to the upper surface of the substrate,
wherein the first conductive pattern vertically overlaps the lower electrode layer and the upper electrode layer on the connection region,
wherein the lower electrode layer contacts a lower surface of the first conductive pattern on the connection region, and
wherein the upper electrode layer contacts an upper surface of the first conductive pattern on the connection region.

13. The semiconductor device of claim 11, wherein a thickness of the first conductive pattern in the second direction is greater than a thickness in the second direction of each of the lower and upper gate conductive layers.

14. The semiconductor device of claim 11, wherein the active layer further includes a first source/drain region and a second source/drain region, and
wherein the channel region is between the first source/drain region and the second source/drain region.

15. The semiconductor device of claim 14, further comprising:
a gate dielectric layer between the channel region of the active layer and the word line;
a bit line electrically connected to the first source/drain region of the active layer, the bit line extending in a vertical direction; and
a data storage structure electrically connected to the second source/drain region of the active layer.

16. A semiconductor device comprising:
a substrate including a memory cell array region, a connection region, and a contact region sequentially arranged in a first direction;
gate electrodes on the memory cell array region and the connection region, and the gate electrodes being stacked and spaced apart from each other in a vertical direction; and
conductive connection patterns on the contact region and the connection region, and the conductive connection patterns being stacked and spaced apart from each other in the vertical direction,
wherein the gate electrodes are electrically connected to the conductive connection patterns on the connection region,
wherein the conductive connection patterns have a step structure including a plurality of step regions spaced apart from each other in the first direction on the contact region, and
wherein the step structure has a first step portion stepping down along the first direction and a second step portion facing the first step portion and stepping up along the first direction.

17. The semiconductor device of claim 16, further comprising active layers on the memory cell array region, the active layers being stacked and spaced apart from each other in the vertical direction,
wherein each of the active layers includes a channel region vertically overlapping the gate electrodes.

18. The semiconductor device of claim 16, wherein the conductive connection patterns include gate pad regions arranged in a step shape at the first step portion of the step structure.

19. The semiconductor device of claim 18, wherein the plurality of step regions have a first step region and a second step region sequentially arranged in the first direction, and
wherein among the gate pad regions of the conductive connection patterns, the gate pad regions in the second step region are at a level lower than the gate pad regions in the first step region.

20. The semiconductor device of claim 16, further comprising:
a first gap-fill insulating pattern;
a second gap-fill insulating pattern; and
interlayer insulating layers alternately stacked with the conductive connection patterns in the vertical direction,
wherein the conductive connection patterns and the interlayer insulating layers are between the first gap-fill insulating pattern and the second gap-fill insulating pattern, and
wherein the interlayer insulating layers extend from the first gap-fill insulating pattern.
